(19) United States
(12) Patent Application Publication
(10) Pub. No.: US 2012/0250275 A1
(43) Pub. Date: Oct. 4, 2012

(54) ELECTRONIC DEVICE, ELECTRONIC COMPONENT, AND METHOD OF MANUFACTURING CIRCUIT BOARD ASSEMBLY

(76) Inventors: Nobuhiro Yamamoto, Tokyo (JP); Takahisa Funayama, Tokyo (JP)

(21) Appl. No.: 13/300,379

(22) Filed: Nov. 18, 2011

(30) Foreign Application Priority Data
Mar. 31, 2011 (JP) 2011-080673

(51) Int. Cl. H05K 5/00; H05K 3/00

(52) U.S. Cl. 361/752; 29/829

(57) ABSTRACT

According to one embodiment, an electronic device includes a housing, a circuit board, an electronic component, a joint, a sealant, and a positioning member. The circuit board is provided in the housing, and includes a first surface and a first conductor on the first surface. The electronic component is located on the first surface of the circuit board, and includes a second surface facing the first surface and a second conductor on the second surface. The joint is located between the first surface and the second surface to electrically connect between the first conductor and the second conductor. The sealant is located at least between the first surface and the second surface. The sealant contains a reductant that reduces an oxide film and seals the joint. The positioning member positions the circuit board and the electronic component.

### CROSS-REFERENCE TO RELATED APPLICATIONS

This application is based upon and claims the benefit of priority from Japanese Patent Application No. 2011-080673, filed Mar. 31, 2011, the entire contents of which are incorporated herein by reference.

### FIELD

Embodiments described herein relate generally to an electronic device, an electronic component, and a method of manufacturing a circuit board assembly.

### BACKGROUND

There have been known circuit board assemblies provided with a circuit board having an electronic component such as a ball grid array (BGA), a chip size package (CSP), a quad flat non-leaded package (QFN), a land grid array (LGA), a flip chip, and the like mounted on its surface.

It is required in such a circuit board assembly that the electronic component be mounted on the circuit board with high accuracy.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate first embodiments of the invention and not to limit the scope of the invention.

FIG. 1 is an exemplary perspective view of a magnetic disk device as an electronic device according to a first embodiment;

FIG. 2 is an exemplary schematic cross-sectional view of an electronic component in a circuit board assembly before being mounted on a circuit board in the first embodiment;

FIG. 3 is an exemplary flowchart of the process of manufacturing the circuit board assembly in the first embodiment;

FIG. 4 is an exemplary schematic cross-sectional view of the electronic component in the circuit board assembly mounted on the circuit board in the first embodiment;

FIG. 5 is an exemplary schematic cross-sectional view of the circuit board assembly in the first embodiment;

FIG. 6 is an exemplary schematic cross-sectional view of an electronic component in a circuit board assembly mounted on a circuit board according to a second embodiment;

FIG. 7 is an exemplary schematic cross-sectional view of the circuit board assembly in the second embodiment;

FIG. 8 is an exemplary schematic cross-sectional view of a circuit board assembly according to a third embodiment;

FIG. 9 is an exemplary schematic cross-sectional view of a circuit board assembly according to a fourth embodiment;

FIG. 10 is an exemplary schematic cross-sectional view of an electronic component in a circuit board assembly mounted on a circuit board according to a fifth embodiment;

FIG. 11 is an exemplary schematic cross-sectional view of the circuit board assembly in the fifth embodiment;

FIG. 12 is an exemplary schematic cross-sectional view of a circuit board assembly according to a sixth embodiment;

FIG. 13 is an exemplary schematic cross-sectional view of an electronic component in a circuit board assembly mounted on a circuit board according to a seventh embodiment;

FIG. 14 is an exemplary schematic plan view of a circuit board assembly according to an eighth embodiment; and

FIG. 15 is an exemplary perspective view of an electronic device according to a ninth embodiment.

### DETAILED DESCRIPTION

In general, according to one embodiment, an electronic device comprises a housing, a circuit board, an electronic component, a joint, a sealant, and a positioning member. The circuit board is provided in the housing, and comprises a first surface and a first conductor on the first surface. The electronic component is located on the first surface of the circuit board, and comprises a second surface facing the first surface and a second conductor on the second surface. The joint is located between the first surface and the second surface to electrically connect between the first conductor and the second conductor. The sealant is located at least between the first surface and the second surface. The sealant contains a reductant that reduces an oxide film and seals the joint. The positioning member is configured to position the circuit board and the electronic component.

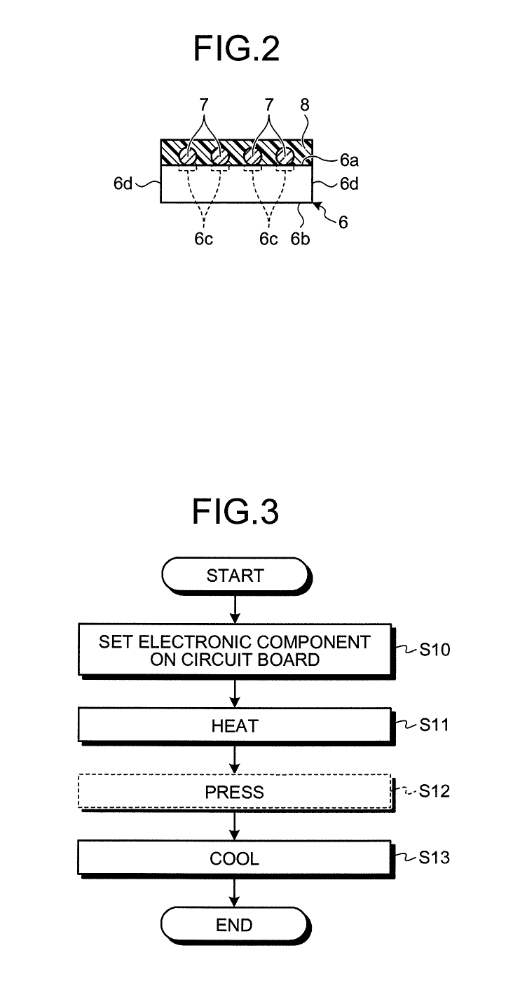

Exemplary embodiments will be described in detail below with reference to the accompanying drawings. In the following embodiments, like elements are designated by like reference numerals, and their description will not be repeated. It is to be noted that FIGS. 2, 4 to 13 illustrate some portions (an electronic component, a weight, etc.) not in cross section.

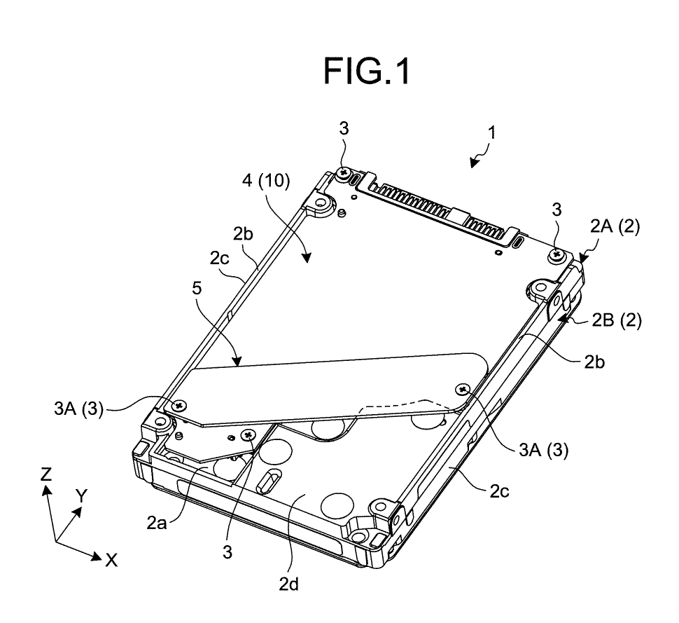

As illustrated in FIG. 1, according to a first embodiment, an electronic device will be described by way of example as a storage device such as a magnetic disk device 1. The magnetic disk device 1 comprises a flat rectangular parallelepiped housing 2, a circuit board 4, and a plate 5. The housing 2 houses components such as a magnetic disk (not illustrated). The circuit board 4 (substrate, printed circuit board, printed wiring board, wiring substrate, rigid flexible printed wiring board, etc.) is attached to the housing 2 with fasteners such as screws 3. The plate 5 (reinforcing board, reinforcing portion, reinforcing member) is attached to the housing 2 with fasteners such as screws 3A. The screws 3A are used to attach the circuit board 4 as well as the plate 5 to the housing 2 and function as coupling parts for the circuit board 4 and the plate 5.

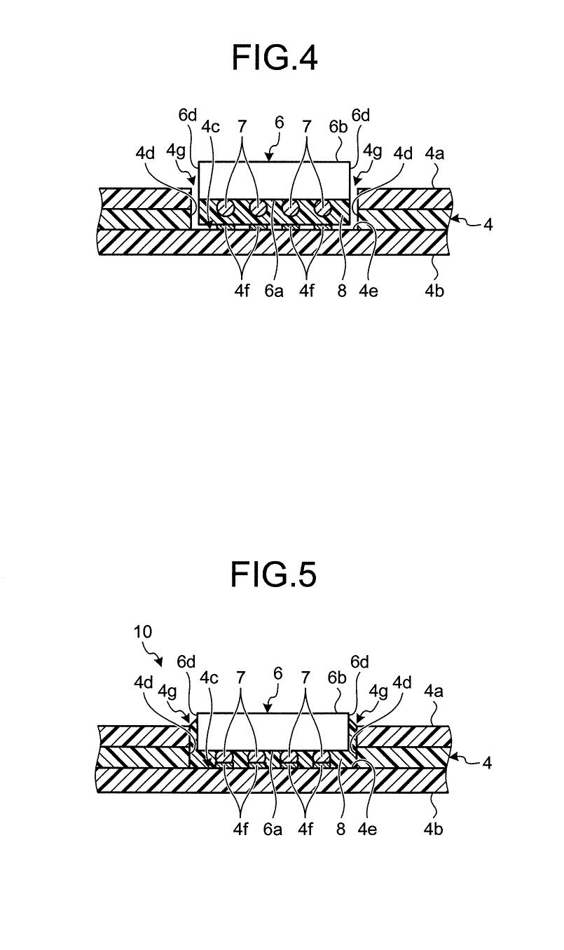

The circuit board 4 is located on an upper wall 2a of the housing 2. In the first embodiment, the circuit board 4 is provided with an electronic component 6 (component, module, device, chip, package, etc., see FIGS. 2 and 4) on a surface 4a (see FIG. 4) that is the back surface of the circuit board 4. A circuit board assembly 10 comprises the circuit board 4 and the electronic component 6 provided to the circuit board 4.

The plate 5 is made of a material having relatively high thermal conductivity (at least higher than that of the circuit board 4) such as a metal material of copper alloy, stainless steel, aluminum alloy, or the like. In the first embodiment, the plate 5 is formed into a flat belt-like shape having a constant thickness and a constant width. Preferably, the plate 5 is made of a material having higher Young's modulus than the circuit board 4.

The housing 2 comprises the upper wall 2a as a rectangular plate-like wall and a plurality of side walls 2c extending along the periphery of the upper wall 2a. The housing 2 is formed of a combination of a plurality of (in the first embodiment, two) divisional bodies 2A and 2B (components, portions). The upper wall 2a is not completely flat but has convex and concave portions. A through hole or the like is formed in the upper wall 2a.

The housing 2 further comprises a bulged portion 2d that is part of the upper wall 2a bulged upward (in the first embodiment, the lower right corner in FIG. 1). On the back side of the bulged portion 2d, the housing 2 houses a voice coil motor (not illustrated) to move a magnetic head (not illustrated) and the like. The housing 2 houses the magnetic disk (not illustrated) on the back side of a lower portion (not illustrated) than the bulged portion 2d. The magnetic disk has front and back surfaces that lie in the XY plane extending in the X and Y directions in FIG. 1, and rotates about the rotation axis (not illustrated) extending in the Z direction. The upper wall 2a is provided with a pair of protruding walls 2b along the long sides of the rectangle in a plan view from the Z direction. The circuit board 4 and the plate 5 are housed in a recess surrounded by the protruding walls 2b.

The electronic component 6 is a surface mount component such as, for example, a ball grid array (BGA), a chip size package (CSP), a quad flat non-leaded package (QFN), a land grid array (LGA), a flip chip, or the like. As illustrated in FIG. 2, the electronic component 6 has, for example, a surface 6a, a surface 6b located opposite and in parallel to the surface 6a, and a surface 6d extending between the surfaces 6a and 6b in a direction crossing (in the first embodiment, perpendicular to) the surfaces 6a and 6b, thereby having a flat and substantially rectangular parallelepiped appearance. Although not illustrated, the electronic component 6 may have a quadrangular (e.g., rectangular or square) appearance in a plan view (from the normal direction of the surface 6a or 6b, from the upside or downside of FIG. 2). One or more electrode (pads) 6c are provided to the surface 6a.

FIG. 2 illustrates the electronic component 6 having undergone preprocessing before being mounted on the circuit board 4. In the first embodiment, before the electronic component 6 is mounted on the circuit board 4, solder balls 7 (conductive bumps) are placed on the electrodes 6c of the electronic component 6, and a sealant 8 is applied to the surface 6a so as to surround the solder balls 7. In the first embodiment, the surface 6a is an example of a second surface, and the surface 6d is an example of outer circumference. Besides, the electrode 6c is an example of a second conductor, and the solder ball 7 is an example of a joint.

The sealant 8 mainly contains, for example, an insulative thermoplastic synthetic resin material. In the first embodiment, preferably, the sealant 8 is solid at temperature (e.g., room temperature) before heating and forms the outer surface (side surface, bottom surface, etc.). In this state, for example, the sealant 8 can be easily placed at a predetermined position on the circuit board 4 and is easy to use.

As illustrated in FIG. 3, in the first embodiment, the electronic component 6 having undergone the preprocessing as illustrated in FIG. 2 is set on the circuit board 4 (S10). The electronic component 6 is then heated, for example, in a reflow furnace, and the solder balls 7 and the sealant 8 are melted (S11). After that, the electronic component 6 is cooled such that the solder balls 7 and the sealant 8 are solidified (S13). During or immediately after the process at S11, the electronic component 6 may be pressed against the circuit board 4 (S12).

As illustrated in FIG. 4, the circuit board 4 has the surface 4a and a surface 4b located opposite and in parallel to the surface 4a. In the first embodiment, as an example, the circuit board 4 is provided with a recess 4c that is capable of housing the electronic component 6. The recess 4c has an opening on the surface 4a side, and is formed quadrangular (e.g., rectangular or square) in a plan view (from a direction along the normal of the surface 4a, from the upside of FIG. 4). Electrodes 4f are provided to a bottom surface 4e, i.e., the bottom of the recess 4c. The electrodes 4f face the electrodes 6c provided to predetermined positions of the electronic component 6, respectively. There is a space 4g between a side surface 4d as the inner circumference of the recess 4c and the surface 6d as the outer circumference of the electronic component 6 housed (placed) in the recess 4c. That is, the recess 4c is larger in plan view than the electronic component 6 by the space 4g. The bottom surface 4e is an example of a first surface, and the electrode 4f is an example of a first conductor. While the circuit board 4 is described by way of example as a multi-layered circuit board, it is not so limited.

In the first embodiment, the sealant 8 contains additives having the function of reducing an oxide film (metal oxide) formed on the surface of metal materials such as the solder balls 7, the electrodes of the electronic component 6 (e.g., copper), and the electrodes 4f of the circuit board 4 (e.g., copper, see FIG. 4). Examples of the additives include carboxylic acid, halogen compound, and the like. In the case of carboxylic acid, the carboxylic acid reacts with the oxide film (metal oxide) to form carboxylate salts and water, which removes the oxide film. Carboxylate salts react with a conductor such as solder and are alloyed. Rosin functions equivalently to the carboxylic acid. In the case of halogen compound (alkyl halide), the halogen compound is resolved by heating into an alkyl group and halogen hydride, and the halogen hydride reacts with the oxide film to form metal halide and water, which removes the oxide film. Such additives facilitate to improve conduction between the electrodes 6c and the solder balls 7 and between the electrodes 4f and the solder balls 7.

However, if the sealant 8 contains such additives, it is likely to be deformed while being heated. Accordingly, if the electronic component 6 with the solder balls 7 and the sealant 8 as illustrated in FIG. 2 is simply placed on the circuit board 4, it may be displaced from a predetermined position, tilted from a predetermined orientation, or the like.

In view of this, according to the first embodiment, a positioning member to position (a guide to guide) the circuit board 4 and the electronic component 6 is provided to at least one of the circuit board 4, the electronic component 6, and another component, which will be described later. In the first embodiment, as an example, the recess 4c includes the positioning member. More specifically, from the state where the electronic component 6 is set on the circuit board 4 before being heated at S11 as illustrated in FIG. 4, the side surface 4d of the recess 4c faces the surface 6d of the electronic component 6. Thus, even if an inertial force, etc. acts on the electronic component 6 to move the electronic component 6 in a direction along the surface 4a, 4b, 4e, or the like, the movement of the electronic component 6 is suppressed by contact between the side surface 4d of the recess 4c and the surface 6d of the electronic component 6.

As illustrated in FIG. 5, the solder balls 7 and the sealant 8 are melted by heating at S11, and thereby the electronic component 6 moves (downward) into the recess 4c of the circuit board 4 by gravity or the like. With this, the solder balls 7 are squashed in the thickness direction of the circuit board 4 (the vertical direction in FIG. 5), which increases the contact area between the electrodes 4f of the circuit board 4 and the electrodes 6c of the electronic component 6, resulting in less volume of an area where the sealant 8 can be present in the recess 4c (an area between the surface 6a of the electronic component 6 in the recess 4c and the bottom surface 4e of the circuit board 4). In the first embodiment, as the volume of this area reduces, the melted sealant 8 flows into the space 4g and can be discharged out of the area through the space 4g. Incidentally, the sealant 8 remains in the space 4g after cooling at S13. The fact that the sealant 8 remains in the space 4g proves that the sealant 8 flows out of the area through the space 4g.

The melted sealant 8 flowing into the space 4g facilitates to position the electronic component 6 in the center of the recess 4c. Besides, by setting the space 4g to an appropriate size according to the viscosity or the like of the sealant 8, the sealant 8 can be discharged easier using the capillary action in the space 4g.

As described above, according to the first embodiment, the sealant 8 contains a reductant that reduces an oxide film. With this, for example, oxide films on the electrodes 4f, the solder balls 7, and the electrodes 6c can be reduced, which reduces the conduction resistance in contact portions between them. Besides, the circuit board 4 is provided with the recess 4c that forms at least part of the positioning member (guide). This facilitates, for example, to reduce the displacement or tilt of the electronic component 6 with respect to the circuit board 4.

According to the first embodiment, the space 4g is provided between the surface 6d as an example of the outer circumference of the electronic component 6 and the side surface 4d as an example of the inner circumference of the recess 4c. This facilitates the flow of the sealant 8 and reduces inconvenience (e.g., tilt or float of the electronic component 6, insufficient squash of the solder balls 7, etc.) caused by the sealant 8 resistant to flow. Moreover, for example, the space 4g around or on both sides of the electronic component 6 facilitates to position the electronic component 6 in the center of the recess 4c.

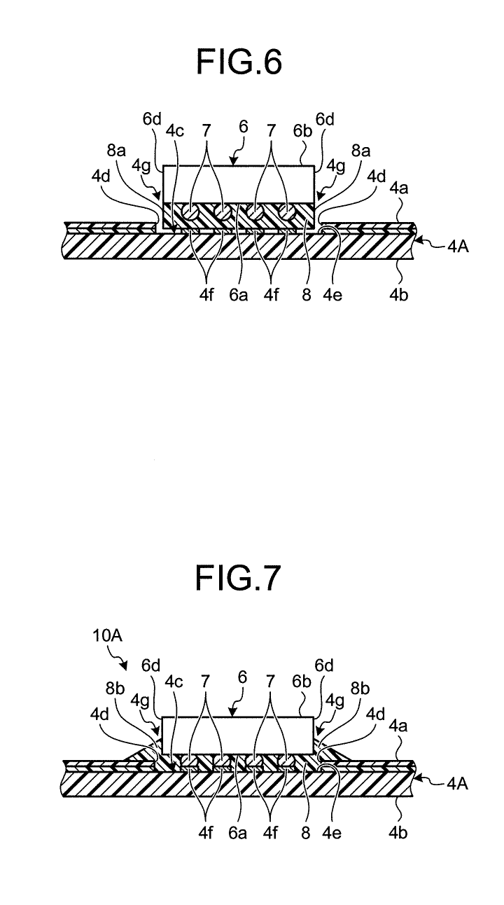

FIG. 7 illustrates a circuit board assembly 10A according to a second embodiment, which can replace the circuit board assembly 10 of the first embodiment. The circuit board assembly 10A can be formed in the same manner as illustrated in FIG. 3. In the second embodiment, as illustrated in FIG. 6. the recess 4c is shallower compared to the first embodiment. That is, in the state illustrated in FIGS. 6 and 7, the surface 6a is located outside the recess 4c. Accordingly, as illustrated in FIG. 6, when the electronic component 6 with the solder balls 7 and the sealant 8 as illustrated in FIG. 2 is placed on a circuit board 4A, a positioning member (guide) is not formed between the electronic component 6 and the recess 4c of the circuit board 4A. Instead, in the second embodiment, a side surface 8a of the sealant 8, which is solid at room temperature before being heated at S11, faces the side surface 4d of the recess 4c, and thereby the recess 4c functions as at least part of the positioning member. Thus, according to the second embodiment also, for example, it is possible to facilitate to reduce the displacement or tilt of the electronic component 6 with respect to the circuit board 4A. Moreover, since the sealant 8 is likely to remain in a predetermined area by the recess 4c, for example, it becomes easier to suppress the displacement of the electronic component 6.

According to the second embodiment, as illustrated in FIG. 7, around the outer circumference of the electronic component 6, a fillet 8b is formed of the sealant 8 melted and flowing out of the recess 4c. This achieves, for example, high connection rigidity and strength between the electronic component 6 and the circuit board 4A.

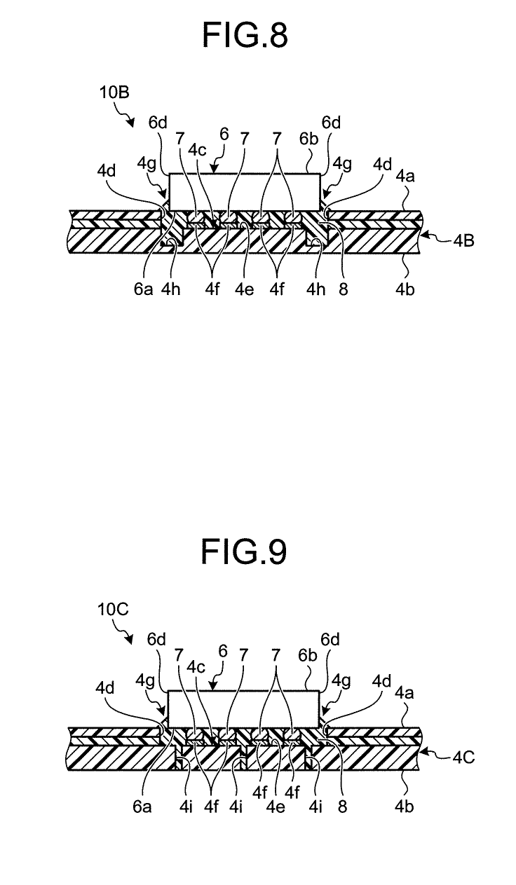

FIG. 8 illustrates a circuit board assembly 10B according to a third embodiment, which can replace the circuit board assembly 10 of the first embodiment. The circuit board assembly 10B can also be formed in the same manner as illustrated in FIG. 3. In the third embodiment, the recess 4c of a circuit board 4B is provided with a recess 4h having an opening on the bottom surface 4e. The recess 4h may be formed in a ring along the outer circumference of the recess 4c, or there may be provided a plurality of the recesses 4h. The sealant 8 can be discharged through the recess 4h. Thus, according to the third embodiment also, for example, it is possible to facilitate the flow of the sealant 8 and reduce inconvenience (e.g., tilt or float of the electronic component 6, insufficient squash of the solder balls 7, etc.) caused by the sealant 8 resistant to flow. The recess 4h is an example of a second recess.

FIG. 9 illustrates a circuit board assembly 100 according to a fourth embodiment, which can replace the circuit board assembly 10 of the first embodiment. The circuit board assembly 10C can also be formed in the same manner as illustrated in FIG. 3. In the fourth embodiment, the recess 4c of a circuit board 4C is provided with a through hole 4i having an opening on the bottom surface 4e and passing through the circuit board 4C between the bottom surface 4e and the surface 4b. The sealant 8 can be discharged through the through hole 4i. Thus, according to the fourth embodiment also, for example, it is possible to facilitate the flow of the sealant 8 and reduce inconvenience (e.g., tilt or float of the electronic component 6, insufficient squash of the solder balls 7, etc.) caused by the sealant 8 resistant to flow. The through hole 4i is an example of a through portion or the second recess.

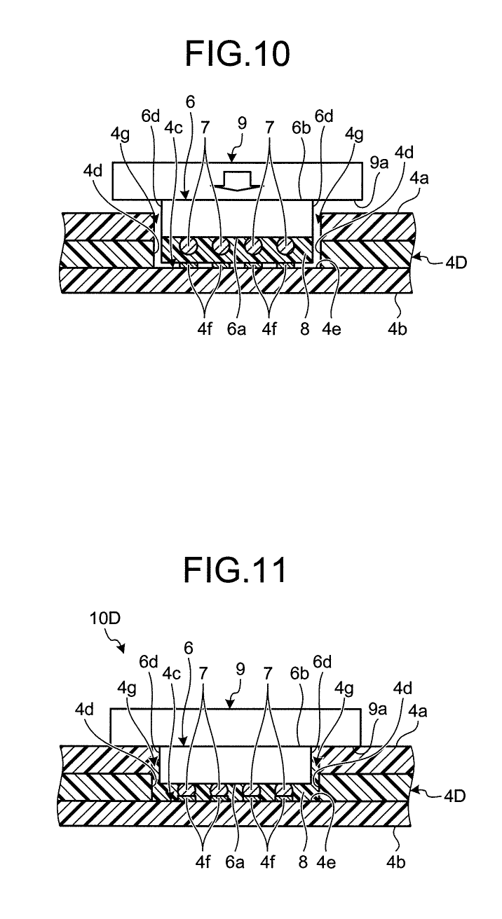

FIG. 11 illustrates a circuit board assembly 10D according to a fifth embodiment, which can replace the circuit board assembly 10 of the first embodiment. The circuit board assembly 10D can also be formed in the same manner as illustrated in FIG. 3. In the fifth embodiment also, as illustrated in FIG. 10, the electronic component 6 with the solder balls 7 and the sealant 8 before being heated at S11 is housed in the recess 4c of a circuit board 4D. However, in the fifth embodiment, as illustrated in FIGS. 10 and 11, a weight 9 is placed on the electronic component 6. The weight 9 applies the weight to press the electronic component 6 toward the circuit board 4D when the solder balls 7 and the sealant 8 are heated and softened at S11. At this point, a surface 9a of the weight 9 comes in contact with the surface 4a of the circuit board 4D. Thus, according to the fifth embodiment also, for example, it is possible to facilitate the flow of the sealant 8 and reduce inconvenience (e.g., tilt or float of the electronic component 6, insufficient squash of the solder balls 7, etc.) caused by the sealant 8 resistant to flow. Besides, for example, the solder balls 7 can be reliably squashed by the weight 9, which further reduces the conduction resistance in contact portions of the electrodes 4f, the solder balls 7, and the electrodes 6c. The weight 9 is an example of a pressing member, a weighting member, or an auxiliary member. The weight 9 may be removed or left on the electronic component 6 to be used as a heat dissipater.

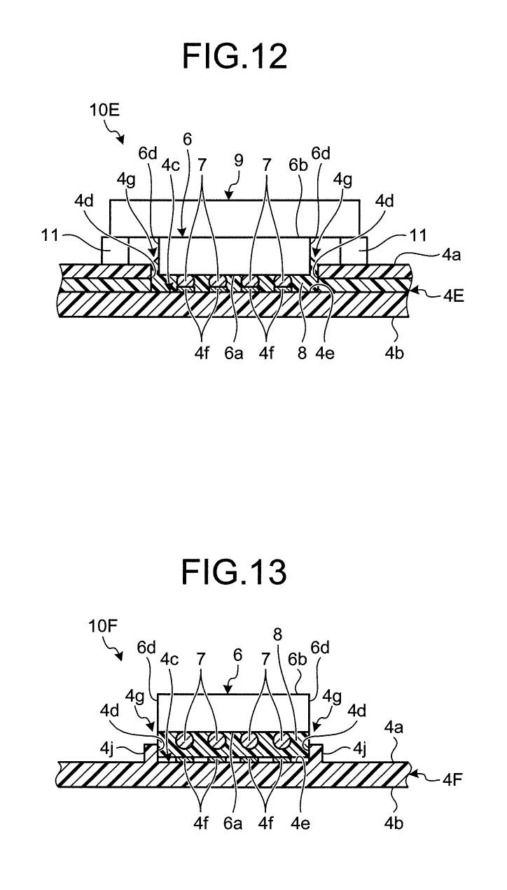

FIG. 12 illustrates a circuit board assembly 10E according to a sixth embodiment, which can replace the circuit board assembly 10 of the first embodiment. The circuit board assembly 10E can also be formed in the same manner as illustrated in FIG. 3. In the sixth embodiment also, as illustrated in FIG. 12, the electronic component 6 with the solder balls 7 and the sealant 8 before being heated at S11 is housed in the recess 4c of a circuit board 4E, and the weight 9 is used as in the fifth embodiment. However, in the sixth embodiment, a spacer 11 is arranged on the circuit board 4E to face the weight 9. In other words, the spacer 11 is located between the circuit board 4E and the weight 9. According to the sixth embodiment, the same effects as in the fifth embodiment can be achieved. Moreover, according to the sixth embodiment, for example, the spacer 11 helps the solder balls 7 be set in a proper shape. The spacer 11 is an example of a jig or a component.

FIG. 13 illustrates a circuit board assembly 10F (before heating and cooling) according to a seventh embodiment, which can replace the circuit board assembly 10 of the first embodiment. The circuit board assembly 10F can also be formed in the same manner as illustrated in FIG. 3. In the seventh embodiment, a protrusion 4j is provided on the surface 4a of a circuit board 4F as a positioning member (guide). The protrusion 4j guides the surface 6d of the electronic component 6 or the side surface of the sealant 8. Thus, according to the seventh embodiment also, for example, it is possible to facilitate to reduce the displacement or tilt of the electronic component 6 with respect to the circuit board 4F.

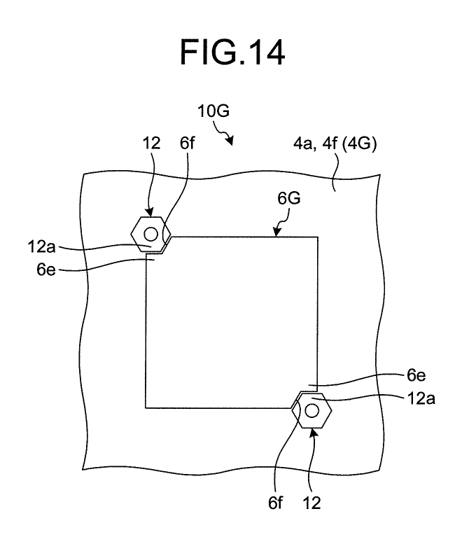

FIG. 14 illustrates a circuit board assembly 10G according to an eighth embodiment, which can replace the circuit board assembly 10 of the first embodiment. The circuit board assembly 10G can also be formed in the same manner as illustrated in FIG. 3. In the eighth embodiment, a hexagonal columnar stud 12 is provided on the surface 4a of a circuit board 4G as a positioning member. Further, in the eighth embodiment, an electronic component 6G is provided with a notch 6f (recess) at a corner 6e. A corner 12a of the stud 12 is fitted in (is put in, corresponds to) the notch 6f. That is, in the eighth embodiment, the electronic component 6G is provided with a recess as a positioning member. Thus, according to the eighth embodiment also, for example, it is possible to facilitate to reduce the displacement or tilt of the electronic component 6G with respect to the circuit board 4G. The stud 12 is an example of a protrusion.

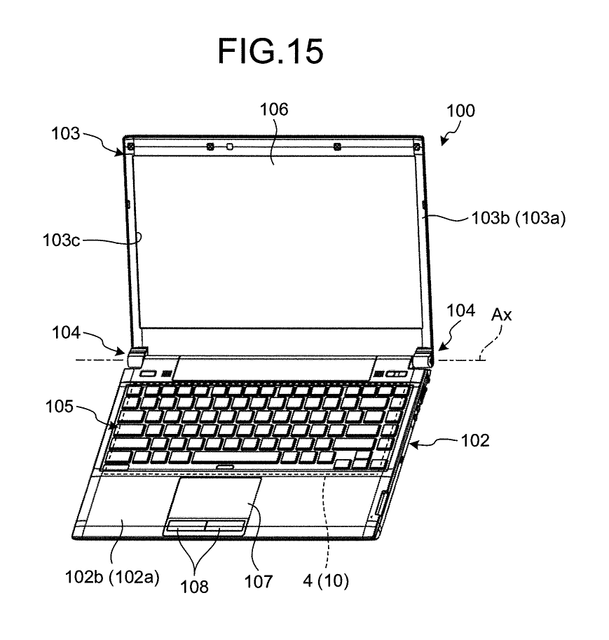

FIG. 15 illustrates an electronic device 100 according to a ninth embodiment. The circuit board assembly 10 (10, 10A to 10G) can be provided to the electronic device 100. The electronic device 100 is, for example, a notebook personal computer (PC). The electronic device 100 comprises a flat rectangular first body 102 and a flat rectangular second body 103. The first body 102 and the second body 103 are connected by a hinge 104 to be relatively rotatable about, for example, a rotation axis Ax between an open position illustrated in FIG. 15 and a closed position (not illustrated).

The first body 102 is provided with a keyboard 105, a pointing device 107, click buttons 108, and the like as input devices, which are exposed on a front surface 102b as the outer surface of a housing 102a (first housing) of the first body 102. The second body 103 is provided with a display 106 such as a liquid crystal display (LCD) as a display device (component). The display 106 is exposed from an opening 103c in a front surface 103b as the outer surface of a housing 103a (second housing) of the second body 103. In the open position as illustrated in FIG. 15, the keyboard 105, the display 106, the pointing device 107, the click buttons 108, and the like are exposed so that the user can use them. On the other hand, in the closed position (not illustrated), the front surface 102b closely faces the front surface 103b, and the keyboard 105, the display 106, the pointing device 107, the click buttons 108, and the like are hidden between the housings 102a and 103a.

The housing 102a of the first body 102 houses components (not illustrated) such as the circuit board assembly 10, a hard disk, a cooling fan, and the like. The circuit board assembly 10 comprises the circuit board 4 having the electronic component 6, a central processing unit (CPU), a read only memory (ROM), a random access memory (RAM), and other components mounted thereon. In the electronic device 100 of the ninth embodiment provided with the circuit board assembly 10 (10, 10A to 10G), the same effects as previously described can be achieved.

The housing 102a of the first body 102 can house the magnetic disk device 1 (not illustrated in FIG. 15) exemplified in the first embodiment. In this case, specifically, for example, the housing 102a is provided with a recess in the back surface (not illustrated) to house the magnetic disk device 1. The magnetic disk device 1 housed in the recess is electrically connected to the circuit board 4 of the electronic device 100 via a connector (not illustrated). Further, a cover (not illustrated) is attached to the back surface of the housing 102a to cover the recess that houses the magnetic disk device 1.

Besides, the internal structures of the magnetic disk device 1 except the housing 2 may be housed in the housing 102a of the electronic device 100. In this case, the housing 102a of the electronic device 100 also serves as a housing of the magnetic disk device 1. The magnetic disk device 1 may be provided in the housing 103a of the second body 103. Further, a plurality of the magnetic disk devices 1 may be provided in the housing 102a of the first body 102.

The specifications (structure, direction, shape, size, length, width, thickness, height, number, arrangement, position, material, etc.) can be suitably modified regarding the electronic device, the storage device, the magnetic disk device, the housing, the circuit board assembly, the circuit board, the first surface, the first conductor, the electronic component, the second surface, the second conductor, the joint, the sealant, the positioning member, the recess, the second recess, the through portion, the protrusion, and the like. In addition, the process blocks can also be suitably modified.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a housing;
a circuit board provided in the housing, the circuit board comprising a first surface and a first conductor on the first surface;
an electronic component on the first surface of the circuit board, the electronic component comprising a second surface facing the first surface and a second conductor on the second surface;
a joint located between the first surface and the second surface to electrically connect between the first conductor and the second conductor;
a sealant located at least between the first surface and the second surface, the sealant containing a reductant that reduces an oxide film and sealing the joint; and
a positioning member configured to position the circuit board and the electronic component.

2. The electronic device of claim 1, wherein
the circuit board comprises a recess,
the first surface is located at bottom of the recess, and
the positioning member comprises at least part of the recess.

3. The electronic device of claim 2, wherein there is a space between outer circumference of the electronic component and inner circumference of the recess, the space containing the sealant.

4. The electronic device of claim 2, wherein the second surface is located outside the recess.

5. The electronic device of claim 2, wherein the circuit board further comprises a second recess having an opening on the first surface, the second recess containing the sealant.

6. The electronic device of claim 5, wherein the second recess is a through portion passing through the circuit board.

7. The electronic device of claim 1, wherein the positioning member comprises a protrusion on the first surface of the circuit board.

8. An electronic component used in the electronic device of claim 1, the electronic component comprising:
the second surface;
the second conductor; and
the positioning member.

9. A method of manufacturing a circuit board assembly comprising:
positioning and placing an electronic component comprising a conductor to which a joint is connected on a circuit board in such a manner that the joint is located on the circuit board side, a sealant, which contains a reductant that reduces an oxide film, being applied around the joint;
heating the circuit board with the electronic component mounted thereon; and
cooling the circuit board after the heating.

10. The method of claim 9, further comprising pressing the electronic component against the circuit board.
